(19) United States
(12) Patent Application Publication
(10) Pub. No.: US 2010/0195308 A1
(43) Pub. Date: Aug. 5, 2010

(54) LIGHT EMITTING DEVICE AND METHOD FOR FABRICATING THEREOF

(75) Inventor: Yu-Feng Lin, Taipei County (TW)

Correspondence Address: QUINTERO LAW OFFICE, PC, 615 Hampton Dr, Suite A202, Venice, CA, 90291, US

(73) Assignee: EVERLIGHT ELECTRONICS CO., LTD.

(21) Appl. No.: 12/699,742

(22) Filed: Feb. 3, 2010

(30) Foreign Application Priority Data
Feb. 3, 2009 (TW) TW98103379

(51) Int. Cl. F21V 9/16; F21V 19/00; F21V 7/00; H01L 21/00

(52) U.S. Cl. 362/84; 362/382; 362/296.01; 438/27; 257/98; 257/E33.059; 257/E33.06; 257/E33.067

(57) ABSTRACT

The invention provides a light emitting device and method for fabricating thereof. The light emitting device includes a body having a cavity with a slanteded sidewall, a light emitting chip, a base and a conductive member, in which the base fits in the body, and the conductive member is formed in the body and extends out of the sidewall of the body along the slanteded sidewall of the cavity.

### CROSS REFERENCE TO RELATED APPLICATIONS

This application claims priority of Taiwan Patent Application No. 98103379, filed on Feb. 3, 2009, the entirety of which is incorporated by reference herein.

### BACKGROUND OF THE INVENTION

1. Field of the Invention

The present invention relates to a light emitting device, and in particular, to a light emitting device with high heat dissipating efficiency and a method for fabricating thereof.

2. Description of the Related Art

Light emitting diodes (LEDs) are solid-state light sources having advantages of long lifespan, low driving voltage, fast operating speed and good shock resistance, thereby allowing LEDs to be applied in a variety of fields.

Generally, LED packages comprise lamp packages and surface mounting device packages. Among the conventional LED packages, surface mounting device packages have advantages of high reliability, large viewing angles and high brightness. Additionally, conventional surface mounting device packages are fabricated adopting light printed circuit boards (PCBs) and reflector cups of polymer materials, thereby having low package weight. However, PCBs and reflector cups made of polymer materials have poor heat dissipating ability, thereby reducing heat dissipating efficiency and causing higher LED package temperatures. Therefore, conventional LED packages, packaged by surface mounting device technology, have reduced lifespan and luminance efficiency.

Thus, a novel light emitting device with high heat dissipating efficiency and a method for fabricating thereof are desired.

### BRIEF SUMMARY OF INVENTION

A light emitting device and method for fabricating thereof are provided. An exemplary embodiment of a light emitting device comprises a body having a cavity with slanteded sidewalls. A light emitting chip disposed in the cavity. A conductive member electrically connects to the light emitting chip, the conductive member is formed in the body and extended out of the body along a direction parallel to the slanted sidewall of the cavity with a specific distance. The light emitting device further comprises a base embedded in the body, extruding out of a bottom of the cavity to carry the light emitting chip. A sidewall of the base comprises a protrusion portion allowing the base to be embedded in the body, thereby improving the bonding strength of the base and the body. The improved bonding strength increases the heat dissipating ability of the base and the body, thus decreasing the temperature of the light emitting device.

An exemplary embodiment of a method for fabricating a light emitting device is providing, comprising: providing a body having a cavity with a slanted sidewall, a hole from a bottom of the body to a surface of the cavity and a channel extending along the slanted sidewall to a sidewall of the body; forming a conductive member in the channel, extending out of the sidewall of the body along the slanted sidewall of the cavity; forming a base in the hole, wherein a surface of the base extends out of a bottom of the body; disposing a light emitting chip on the surface of the body.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1 to 3 are cross section views showing one exemplary embodiment of a light emitting device of the invention.

### DETAILED DESCRIPTION OF INVENTION

The following description is of a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice of the invention.

The present invention will be described below with respect to fabricating a light emitting device, for example, encapsulating a light emitting diode (LED) by surface mounting. It is to be understood that, however, exemplary embodiments of a light emitting device can applied to electronic devices, for example, remote controllers such as image remote controllers or door entry controllers, optical sensors such as smoke detectors or local area network signal transceivers or optical input devices such as an optical mice.

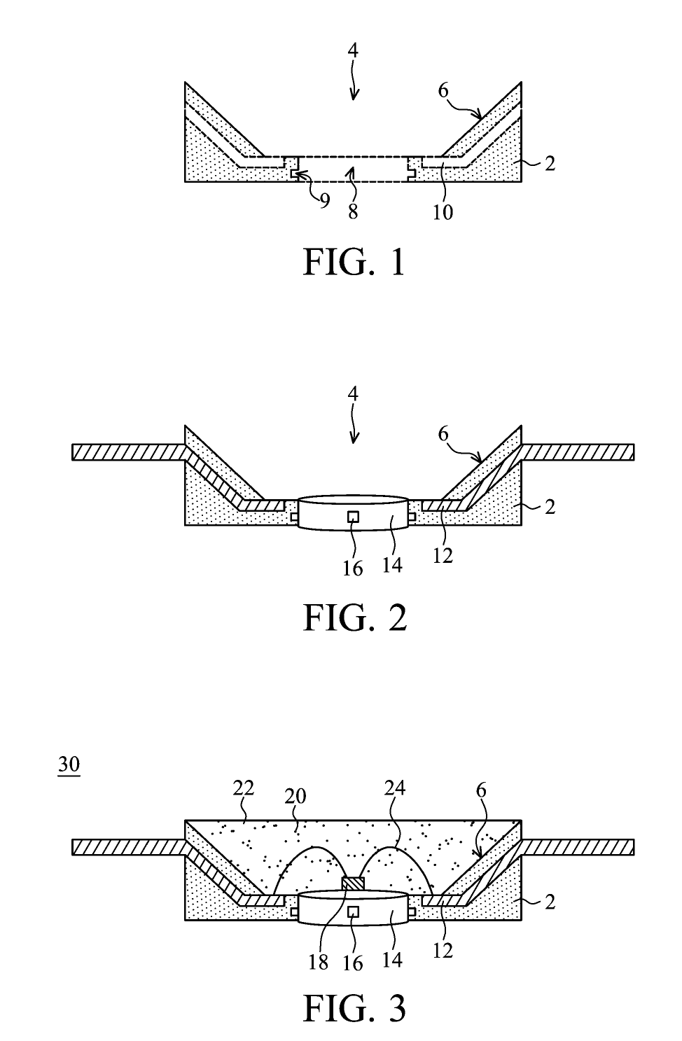

FIGS. 1 to 3 are cross section views showing one exemplary embodiment of a light emitting device of the invention. As shown in FIG. 1, a body 2 is provided having a cavity 4 with a slanted sidewall 6. The body 2 further comprises a hole 8 from a bottom of the body 2 to a surface of the cavity 4. A sidewall of the hole 8 has a recess 9 serving as a portion to wedge a component formed in subsequent processes. As shown in FIG. 1, a channel 10 is formed in the body 2. The channel 10 extends from the bottom of the cavity 4 to a sidewall of the body 2 along the slanted sidewall 6 of the cavity 4, wherein the channel 10 is parallel to the slanted sidewall 6 with a specific distance. The channel 10 may serve as a flow passageway of a liquid metal provided in subsequent processes.

The body 2 may comprise a high temperature ceramic material, for example, aluminum oxide (Al₂O₃), aluminum nitride (AlN), boron nitride (BN) or other suitable high temperature insulating materials. In one embodiment, fabrication of the body 2 may comprise, firstly, providing a wax mold (not shown) corresponding to the body 2. For example, the wax mold may comprise a channel portion corresponding to the channel 10 and a hole portion corresponding to the hole 8, thereby reserving formation positions for the subsequent channel 10 and the hole 8.

Next, a grout, for example, a ceramic material, is poured into the wax mold. A preliminary air drying process is then performed to remove a portion of moisture in the grout. Next, a first stage thermal treatment process is performed to harden the grout. A turning process is then performed, thereby shaping the ceramic grout. Next, the shaped ceramic grout is subjected to a thermal sintering process to reduce porosity thereof. After performing the thermal sintering process, the formation of the body 2 is complete.

It is noted that during the formation processes of the body 2, the temperature of the first stage thermal treatment process may be lower then the sintering temperature. Additionally, during the first stage thermal treatment process, the hole 8 and the channel 10 of the body 2 are substantially shaped. The wax mold is present in the formed hole 8 and the channel 10. During a subsequent thermal sintering process, the wax mold may be melted at a high temperature, thereby removing it from the body 2.

As shown in FIG. 2, after the formation of the body 2, a conductive member 12 is formed in the channel 10. The conductive member 12 may extend out of the sidewall of the body 2 along a direction parallel to the slanted sidewall 6 of the cavity 4. Additionally, during formation of the conductive member 12, a base 14 is formed in the hole 8 of the body 2. The base 14 may be embedded in the recess 9 of the sidewall of the hole 8 by a protrusion portion 16 formed on the sidewall of the base 14, so that the base 14 may be allowed to be embedded in the body 2. Therefore, the bonding strength between the base 14 and the body 2 can be improved.

In one embodiment, the formation of the conductive member 12 and the base 14 may comprise providing a melted liquid metal, for example, melted copper of a melted alloy. Next, the melted liquid metal is filled into the body 2, and cooled down in an environment that prevents the metal from oxidation. Therefore, forming the conductive member 12 and the base 14. It is understand that the conductive member 12 and the base 14 may comprise other suitable conductive materials with high thermal conducting ability. Additionally, the conductive member 12 and the base 14 may be formed in different fabricating steps using different materials. Also, the cooling down process may be performed in an inert gas atmosphere, for example, argon gas, to prevent the metal from oxidation. Further, the liquid metal filling process is performed after the formation of the body 2, thereby preventing the conductive member 12 and the base 14 from device short problems due to thermal diffusion of metal.

As shown in FIG. 3, a light emitting chip 18 is provided on the base 14 of the body 2, electrically connected to the conductive member 12 by a conductive wire 24. Next, an encapsulant 22 with a phosphor powder 20 dispersed therein is filled into the cavity 4 of the body 2 to cover the light emitting chip 18. Therefore, the light emitting device 30 is formed complete.

In one embodiment, the light emitting chip 18 may comprise a blue light emitting diode with a yellow phosphor powder, for example, YAG, to form a white light emitting device. Alternatively, the light emitting chip 18 may comprise an ultraviolet light emitting diode with a red, blue or green phosphor powder to form a white light emitting device. It is understand that the ultraviolet light emitting diode may also have a single color phosphor powder to form a single color light emitting diode. Moreover, the encapsulant 22 may comprise epoxy, and the conductive wire 24 may comprise a gold wire.

FIG. 3 shows one exemplary embodiment of a light emitting device 30 of the invention. In FIG. 3, a body 2 has a cavity 4 with a slanted sidewall 6. A conductive member 12 is formed in the body 2, extending out of the body 2 along the slanted sidewall 6 of the body 2. As shown in FIG. 3, a base 14 is embedded in the body 2, wherein a side of the base 14 is extruded from a bottom of the cavity 4. The conductive member 12 is electrically connected to a light emitting chip 18 by a conductive wire 24. The conductive member 12 is isolated from the slanted sidewall 6 with a specific distance, extending out of the body 2. Further, as shown in FIG. 3, an encapsulant 22 with a phosphor powder 20 dispersed therein is formed in the cavity 4, covering the light emitting chip 18.

The slanted sidewall 6 of the cavity 4 may serve as a reflective surface to reflect the light emitting from the light emitting chip 18 and the luminescent phosphor powder 20, thereby improving luminescence efficiency of the light emitting device 30. Additionally, the spacing distance between the conductive member 12 and the reflective surface is related to the size of the light emitting device. Note that the conductive member 12 may be formed as close to the reflective surface as possible to improve heat dissipating efficiency.

Note also that the base of one exemplary embodiment of a light emitting device of the invention is a base having high thermal conductivity. Therefore, during operation of the light emitting device 3, the base may facilitate heat generated from the light emitting chip to transfer to the atmosphere quickly. Additionally, the conductive member is disposed in the body, extending to the atmosphere along a direction parallel to the reflective surface. Therefore, when the light emitting device is turned on, heat generated from the light emitting chip in the cavity may transfer to the atmosphere outside of the light emitting device through the conductive member under the reflective surface. Accordingly, one exemplary embodiment of a light emitting device of the invention has high heat dissipating efficiency to reduce temperature thereof. Therefore the lifespan of the light emitting device is extended and luminescence efficiency of the light emitting device is improved, when compared to conventional light emitting devices.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting device, comprising:
a body, having a cavity with a slanted sidewall;
a light emitting chip, disposed in the cavity; and
a conductive member, electrically connected to the light emitting chip, wherein the conductive member is formed in the body and extended out of the body along the slanted sidewall of the cavity.

2. The light emitting device as claimed in claim 1, wherein the conductive member is parallel to the slanted sidewall of the cavity with a predetermined distance.

3. The light emitting device as claimed in claim 1, wherein the body comprises a ceramic material.

4. The light emitting device as claimed in claim 3, wherein the body comprises aluminum oxide, aluminum nitride or boron nitride.

5. The light emitting device as claimed in claim 1, further comprising:
a hole passed through from a bottom of the body to a surface of the cavity; and
a base embedded in the hole of the body, a side of the base is extruded from a bottom of the cavity.

6. The light emitting device as claimed in claim 5, wherein the base comprises a protrusion portion allowing the base to be embedded in the body.

7. The light emitting device as claimed in claim 5, wherein the conductive member and the base comprise the same materials.

8. The light emitting device as claimed in claim 5, wherein the conductive member and the base comprise different materials.

9. The light emitting device as claimed in claim 5, wherein the conductive member or the base comprise copper or cooper alloy.

10. The light emitting device as claimed in claim 1, wherein the conductive member is electrically connected to the light emitting chip through a conductive wire.

11. The light emitting device as claimed in claim 5, wherein the light emitting chip is disposed on a surface of the base.

12. The light emitting device as claimed in claim 5, wherein the slanted sidewall of the cavity is a reflective surface, the conductive member is embedded in the body under the reflective surface which is parallel to the reflective surface with a specific distance.

13. The light emitting device as claimed in claim 11, further comprising:
an encapsulant filled into the cavity, covering the light emitting chip; and
a phosphor powder dispersed in the encapsulant.

14. A method for fabricating a light emitting device, comprising:
providing a body having a cavity with a slanted sidewall, a hole from a bottom of the body to a surface of the cavity and a channel extending along the slanted sidewall to a sidewall of the body;
forming a conductive member in the channel, the conductive member extending out of the body along the slanted sidewall of the cavity;
forming a base in the hole, wherein a surface of the base extends out of a bottom of the body; and
disposing a light emitting chip on the surface of the body.

15. The method for fabricating a light emitting device as claimed in claim 14, wherein forming of the body comprises the steps of:
providing a mold corresponding to the body;
pouring a grout into the mold;
performing a thermal treatment to shape the body; and
performing a thermal sintering process.

16. The method for fabricating a light emitting device as claimed in claim 14, wherein forming of the conductive member and the base comprise the steps of:
filling a melted liquid metal into the channel and the hole of the body; and
cooling the melted liquid metal to form the conductive member and the base.

17. The method for fabricating a light emitting device as claimed in claim 14, further comprising filling an encapsulant with a phosphor powder dispersed therein to cover the light emitting chip.
